(19) United States
(12) Patent Application Publication
(10) Pub. No.: US 2025/0239526 A1
(43) Pub. Date: Jul. 24, 2025

(54) SEMICONDUCTOR MEMORY DEVICE

(71) Applicant: Kioxia Corporation, Tokyo (JP)

(72) Inventor: Hikaru ARAKAWA, Yokkaichi (JP)

(73) Assignee: Kioxia Corporation, Tokyo (JP)

(21) Appl. No.: 18/820,533

(22) Filed: Aug. 30, 2024

(30) Foreign Application Priority Data
Jan. 19, 2024 (JP) 2024-006781

(51) Int. Cl. H01L 23/532; H01L 23/528; H10B 43/10; H10B 43/27; H10B 43/35

(52) U.S. Cl. CPC H01L 23/53295; H01L 23/5283; H10B 43/10; H10B 43/27; H10B 43/35

(57) ABSTRACT

A semiconductor memory device includes a bit line, a first stacked body arranged above the bit line, the first stacked body including a plurality of first conductive layers alternately stacked in a first direction, the first stacked body including a first stairs region and a first bridge region, and a second stacked body arranged above the first stacked body, the second stacked body including a plurality of second conductive layers alternately stacked in the first direction, the second stacked body including a second stairs region and a second bridge region. A width of a lowest layer of the plurality of first conductive layers of the first bridge region in the third direction is larger than a width of a lowest layer of the plurality of second conductive layers of the second bridge region in the third direction.

### CROSS-REFERENCE TO RELATED APPLICATION(S)

This application is based upon and claims the benefit of priority from the prior Japanese Patent Application No. 2024-006781, filed on Jan. 19, 2024, the entire contents of which are incorporated herein by reference.

### FIELD

Embodiments described herein relate generally to a semiconductor memory device.

### BACKGROUND

Semiconductor packaging using a NAND flash memory as semiconductor memory devices are known. In order to increase the capacity of such a NAND flash memory, a three-dimensional NAND flash memory having a structure in which many memory cells are stacked has been put into practical use. In such a stacked three-dimensional NAND flash memory, it is an object to improve the operating speed and reliability.

### BRIEF DESCRIPTION OF THE DRAWINGS

FIG. 1 is a cross-sectional view showing an entire configuration of a semiconductor memory device according to an embodiment.

FIG. 2 is a cross-sectional view showing a configuration of a memory cell array of a semiconductor memory device according to an embodiment.

FIG. 3 is a cross-sectional view showing a configuration of a memory cell of a semiconductor memory device according to an embodiment.

FIG. 4 is a perspective view schematically showing a connecting region of a semiconductor memory device according to an embodiment.

FIG. 5 is an enlarged perspective view showing an outline of a connecting region of a semiconductor memory device according to an embodiment.

FIG. 6 is a perspective view showing an exemplary configuration of a word line of a semiconductor memory device according to an embodiment.

FIG. 7A is an enlarged top view showing a connecting region of a semiconductor memory device according to an embodiment.

FIG. 7B is an enlarged cross-sectional view showing a connecting region of a semiconductor memory device according to an embodiment.

### DESCRIPTION OF EMBODIMENTS

Hereinafter, a semiconductive memory device according to the present embodiment will be described in detail with reference to the drawings. In the following description, elements having substantially the same functions and configurations are denoted by the same reference signs or the same reference signs followed by alphabetic characters, and will be described redundantly only when necessary. Each of the embodiments described below exemplifies a device and a method for embodying a technical idea of this embodiment. Various modifications may be made to the embodiments without departing from the spirit of the disclosure. These embodiments and modifications thereof are included in the scope of the disclosure described in the claims and equivalents thereof.

In the drawings, the widths, thicknesses, shapes, and the like of the respective portions may be schematically represented in comparison with the actual embodiments for clarity of explanation, but the drawings are merely examples, and do not limit the interpretation of the present disclosure. In the present specification and the drawings, elements having the same functions as those described with respect to the above-described drawings are denoted by the same reference signs, and redundant descriptions thereof may be omitted.

In the present specification, the expression “a includes A, B, or C” does not exclude the case where a includes a plurality of combinations of A to C unless otherwise specified. Furthermore, these expressions do not exclude the case where a includes other elements.

The following embodiments can be combined with each other as long as there is no technical inconsistency.

In the embodiments of the present disclosure, a direction from a substrate toward a memory cell is referred to as above. Conversely, a direction from the memory cell to the substrate is referred to as below. As described above, for convenience of explanation, the term “above” or “below” is used for description, but the configuration may be such that the vertical relationship between the substrate and the memory cell is opposite to that shown in the figure. Furthermore, in the following explanation, for example, the expression “memory cell on substrate” merely describes the vertical relationship between the substrate and the memory cell as described above, and another member may be arranged between the substrate and the memory cell.

A semiconductor memory device according to an embodiment includes a bit line, a first stacked body arranged above the bit line, the first stacked body including a plurality of first insulating layers and a plurality of first conductive layers alternately stacked one by one in a first direction, the first stacked body including a first stairs region and a first bridge region, and a second stacked body arranged above the first stacked body, the second stacked body including a plurality of second insulating layers and a plurality of second conductive layers alternately stacked one by one in the first direction, the second stacked body including a second stairs region and a second bridge region. The first stairs region in which the ends of the plurality of first conductive layers are stepped in a second direction intersecting the first direction in a center of the second direction. The first bridge region arranged adjacent to the first stairs region in a third direction intersecting the first and second directions, and the first bridge region electrically connects memory cell regions on both sides of the first stairs region in the second direction for each of the plurality of first conductive layers. The second stairs region in which the ends of the plurality of second conductive layers are stepped in the second direction in the center of the second direction. The second bridge region arranged adjacent to the second stairs region in the third direction, and the second bridge region electrically connects memory cell regions on both sides of the second stairs region in the second direction for each of the plurality of second conductive layers. A width of a lowest layer of the plurality of first conductive layers of the first bridge region in the third direction is larger than a width of a lowest layer of the plurality of second conductive layers of the second bridge region in the third direction.

### [Overall Configuration of Semiconductor Memory Device]

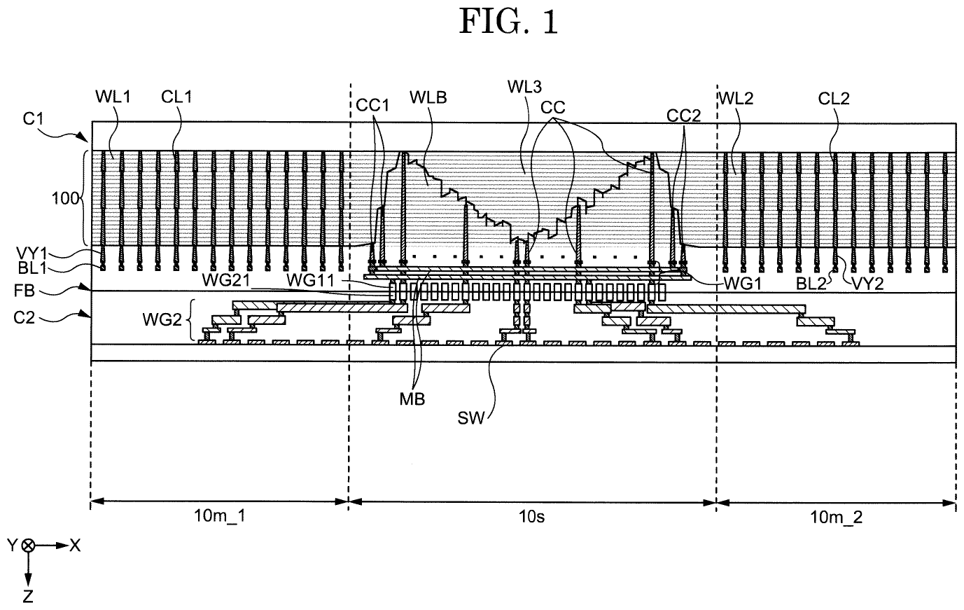

An overall configuration of the semiconductor memory device according to the present embodiment will be described with reference to FIG. 1. FIG. 1 is a cross-sectional view showing an exemplary configuration of a semiconductor memory device 1 according to the present embodiment. The semiconductor memory device 1 is configured by bonding together a memory chip C1 and a CMOS (Complementary Metal Oxide Semiconductor) chip C2. The memory chip C1 is a semiconductor chip including memory cell arrays 10m_1 and 10m_2 and a connecting region 10s. The CMOS chip C2 is a semiconductor chip including a peripheral circuit. The memory chip C1 and the CMOS chip C2 are bonded to each other on a bonding surface FB.

The memory cell array 10m_1 includes a stacked body 100 including a plurality of word lines WL1 stacked in a direction Z and insulated from each other, a plurality of columnar body portions CL1 extending in the direction Z in the plurality of word lines WL1, and a plurality of bit lines BL1 arranged on the stacked body 100. The columnar body portion CL1 is electrically connected to any one of the bit lines BL1 through a via contact VY1. The bit line BL1 is electrically connected to the CMOS chip C2 through a wiring (not shown).

The memory cell array 10m_2 includes the stacked body 100 including a plurality of word lines WL2 stacked in the direction Z and insulated from each other, a plurality of columnar body portions CL2 extending in the direction Z in the plurality of word lines WL2, and a plurality of bit lines BL2 arranged on the stacked body 100. Each layer of the word line WL2 corresponds to each layer of the word line WL1. The columnar body portion CL2 is electrically connected to any one of the bit lines BL2 through the via contact VY2. The bit line BL2 is electrically connected to the CMOS chip C2 through a wiring (not shown). The configurations of the memory cell arrays 10m_1 and 10m_2 may be the same.

The connecting region 10s is arranged between the memory cell array 10m_1 and the memory cell array 10m_2. The connecting region 10s is arranged substantially at the center of the memory chip C1 in the direction X. The connecting region 10s includes a plurality of word lines WL3 stacked in the direction Z. The plurality of word lines WL3 is configured in a stepped shape so as to be closest to the CMOS chip C2 in an intermediate portion of the connecting region 10s and separated from the CMOS chip C2 at an end portion close to the memory cell arrays 10m_1 and 10m_2 on both sides of the intermediate portion of the connecting region 10s. That is, the plurality of word lines WL3 is configured in a stepped shape so as to be separated from the CMOS chip C2 as it approaches the intermediate portion of the connecting region 10s to the memory cell arrays 10m_1 and 10m_2. In addition, the direction of the stairs is an example, and is not necessarily limited to this. For example, the stairs may be configured to approach the CMOS chip C2 as it approaches the memory cell arrays 10m_1 and 10m_2 from the intermediate portion of the connecting region 10s. As the stairs approaches the memory cell array 10m_1 from the end portion of the memory cell array 10m_2 side in the connecting region 10s, the stairs may be a configuration that approaches the CMOS chip C2 or a configuration in the opposite direction. The plurality of word lines WL3 stacked in the direction Z is exposed from the word line WL3 of the upper stage (the CMOS chip C2 side) on each step surface (terrace region) configured in a stepped shape. In addition, when viewed locally, the plurality of word lines WL3 may be configured to approach the CMOS chip C2 as it approaches the memory cell arrays 10m_1 and 10m_2 from the intermediate portion.

Each layer of the word line WL3 corresponds to each layer of the word line WL1 and each layer of the word line WL2. The word lines WL1 to WL3 are approximately the same height in the corresponding layers. Each layer of the word lines WL1 to WL3 is formed by processing consecutive layers of the same material. For example, a conductive material such as copper or tungsten is used as the word lines WL1 to WL3. Hereinafter, each layer of the word lines WL1 to WL3 corresponding to each other is also referred to as a word line layer WL. The plurality of word line layers WL stacked in the direction Z and insulated from each other is also referred to as the stacked body 100.

In the word line layer WL, the word line WL3 is electrically connected to the word line WL1 and the word line WL2 via a bridge member WLB. The bridge member WLB is formed by processing the same material layer as the word lines WL1 to WL3. The bridge member WLB is a layer remaining in the direction Y when the word line WL3 is processed into a stepped shape, and is contiguously arranged in the word lines WL1 to WL3. Each word line layer WL of the word lines WL1 to WL3 is electrically connected by the bridge member WLB.

The plurality of word line layers WL may include a word line layer WL in which no bridge member WLB is arranged. In the word line layer WL without the bridge member WLB, a metal bridge MB is arranged between the word line WL1 and the word line WL2. The metal bridge MB is a wiring layer arranged separately from the word lines WL1 to WL3 of the word line layer WL, and electrically connects the word line WL1 and the word line WL2. Contact plugs CC1 and CC2 connected to the metal bridge MB are connected to the word lines WL1 and WL2 at both ends of the connecting region 10s. The metal bridge MB is connected between the contact plug CC1 connected to the word line WL1 of one end of the connecting region 10s and the contact plug CC2 connected to the word line WL2 of the other end of the connecting region 10s. The contact plug CC1 is connected between the metal bridge MB and the word line WL1. The contact plug CC2 is connected between the metal bridge MB and the word line WL2.

The plurality of word lines WL3 is electrically connected to the contact plug CC extending in the direction Z at each step surface (terrace region) configured in a stepped shape. Furthermore, as shown in FIG. 1, a diameter of the contact plug CC (diameter in the direction X or Y) is tapered so as to become narrower toward the substrate side of the stacking direction (direction Z) in the stacked body 100.

The contact plug CC connected to the word line WL3 is electrically connected to a wiring WG11 via a wiring WG1. The wiring WG11 is a wiring exposed on a bonding surface FB of the memory chip C1 and a CMOS chip C2, and is bonded to a wiring WG21 on the CMOS chip C2 side on the bonding surface FB.

The CMOS chip C2 includes a plurality of switches SW, and the wirings WG2 and WG21. The switch SW is part of a row decoder module, and is composed of, for example, a MOSFET (Field Effect Transistor). The switch SW is connected to the wiring WG21 via the multi-layer wiring structure wiring WG2.

Each switch SW applies a word line voltage to the word line WL (the word lines WL1 to WL3) connected thereto. For example, a switch selected from the plurality of switches SW becomes conductive in a read operation, a write operation, and an erase operation, so that the word line voltage can be applied to the selected word lines WL1 to WL3.

The plurality of switches SW is arranged corresponding to each of the plurality of word line layers WL. Each of the plurality of switches SW is electrically connected to the contact plug CC connected to the word line layer WL. The word line WL3 is configured in a stepped shape so as to be closest to the switch SW in the intermediate portion of the connecting region 10s and separated from the switch SW in the direction Z toward the end portion of the connecting region 10s close to the memory cell arrays 10m_1 and 10m_2. The contact plug CC contacts the step surface (terrace region) arranged in the stepped word line WL3 from the direction Z. The switch SW is electrically connected to the corresponding word line WL3 via the contact plug CC.

### [Configuration of Memory Cell Array]

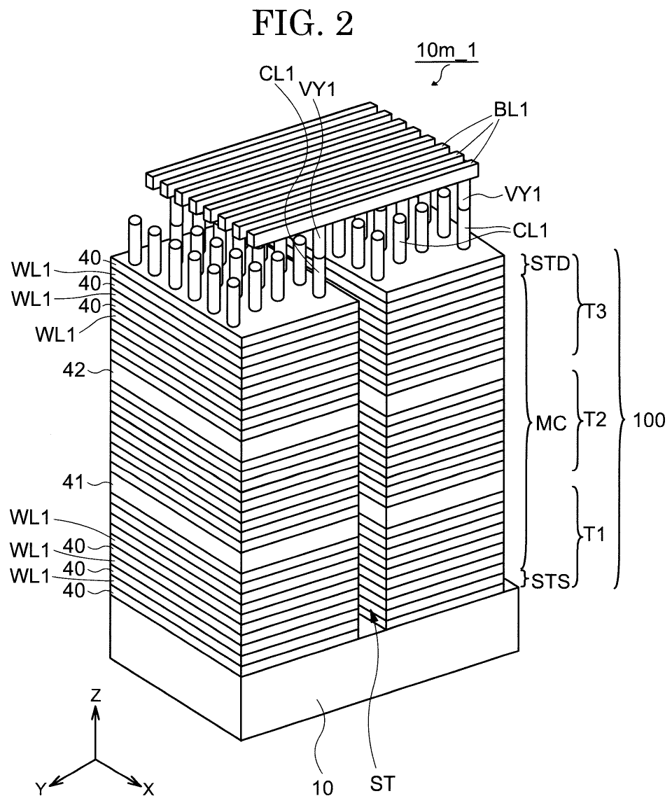

A configuration of the memory cell array according to the present embodiment will be described with reference to FIG. 2. FIG. 2 is a perspective view showing a configuration of a memory cell array according to the present embodiment. In addition, FIG. 2 shows the memory chip C1 upside down with respect to FIG. 1. Furthermore, since the configurations of the memory cell arrays 10m_1 and 10m_2 may be the same, the memory cell array 10m_1 will be described and the description of the memory cell array 10m_2 will be omitted. In FIG. 2, two directions parallel to a main surface of a substrate 10 and perpendicular to each other are referred to as the direction X and the direction Y, and a plane parallel to the main surface of the substrate 10 is referred to as an XY plane. A direction perpendicular to both the direction X and the direction Y is referred to as the direction Z (stacking direction).

As shown in FIG. 2, the memory cell array 10m_1 includes the substrate 10, the stacked body 100 arranged on the substrate 10, the plurality of columnar body portions CL1, and the plurality of bit lines BL1 arranged on the stacked body 100.

For example, the substrate 10 is a semiconductor substrate made of P-type silicon (Si) containing a P-type impurity such as boron (B). For example, a P-type well region containing a P-type impurity is arranged on a surface of the substrate 10. However, the present disclosure is not limited to this, a polysilicon layer may be formed between the substrate 10 and the stacked body 100, and the substrate 10 may be peeled off after the memory chip C1 and the CMOS chip C2 are bonded.

The stacked body 100 includes a lower layer stacked body T1 arranged on the substrate 10, a middle layer stacked body T2 arranged on the opposite side of the substrate 10 of the lower layer stacked body T1, and an upper layer stacked body T3 arranged on the opposite side of the lower layer stacked body T1 of the middle layer stacked body T2 (where the lower layer stacked body T1, the middle layer stacked body T2, and the upper layer stacked body T3 are referred to as the stacked body 100 when they are not distinguished from each other).

The stacked body 100 includes the plurality of word lines WL1 stacked on the substrate 10. The plurality of word lines WL1 and a plurality of insulating layers 40 are alternately stacked one by one periodically in a direction (stacking direction) perpendicular to the main surface of the substrate 10. Each word line WL1 is a single layer. In other words, in the case where the cross-sectional shape of one word line WL1 is observed, a single material may be contiguously formed in a thickness direction (direction Z) of the word line WL1. In addition, there may be no interface within one word line WL1. For example, the material of the word line WL1 may be tungsten.

The insulating layer 40 is formed between the word lines WL1 adjacent to each other in the stacking direction. The plurality of word lines WL1 and the plurality of insulating layers 40 are alternately arranged. The insulating layer 40 is also formed between the substrate 10 and the word line WL1 in the lowest layer. An insulating layer 41 is arranged at a boundary between the lower layer stacked body T1 and the middle layer stacked body T2. A thickness of the insulating layer 41 in the stacking direction arranged at the boundary between the lower layer stacked body T1 and the middle layer stacked body T2 may be larger than a thickness of the insulating layer 40 in the stacking direction between the other word lines WL1. An insulating layer 42 is arranged at a boundary between the middle layer stacked body T2 and the upper layer stacked body T3. A thickness of the insulating layer 42 in the stacking direction arranged at the boundary between the middle layer stacked body T2 and the upper layer stacked body T3 may be larger than the thickness of the insulating layer 40 in the stacking direction between the other word lines WL1. However, the present disclosure is not limited to this, the thicknesses of the insulating layer 41 and the insulating layer 42 in the stacking direction may be the same as the thickness of the insulating layer 40 in the stacking direction between the other word lines WL1.

The word lines WL1 adjacent to each other may be insulated from each other, and for example, the materials of the insulating layer 40, the insulating layer 41, and the insulating layer 42 may be silicon oxide such as silicon dioxide (SiO₂), or TEOS (Tetra Ethyl Ortho Silicate). For example, the insulating layer 40 is deposited using a CVD (Chemical Vapor Deposition) device.

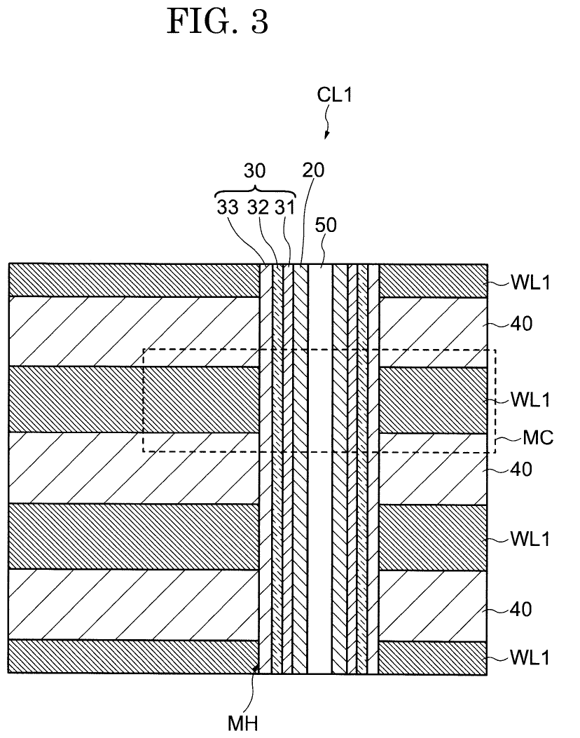

The plurality of word lines WL1 insulated from each other and slits ST and an opening MH common to the plurality of word lines WL1 are arranged in the stacked body 100. The slits ST and the opening MH extend in the stacking direction (direction Z) and passes through the stacked body 100 to reach the substrate 10. The slit ST extends in the direction X and separates the stacked body 100 into a plurality of blocks BLK in the direction Y. Although details will be described later, the columnar body portion CL1 is formed in the opening MH (see FIG. 3).

The columnar body portion CL1 is formed as a cylinder extending within the stacked body 100 in the stacking direction. For example, the plurality of columnar body portions CL1 is arranged in a staggered manner. Alternatively, the plurality of columnar body portions CL1 may be arranged in a square lattice along the direction X and the direction Y.

Furthermore, as shown in FIG. 1, a diameter of the columnar body portion CL1 (the diameter in the direction X or Y) is tapered so as to become narrower toward the substrate side of the stacking direction (direction Z) in each of the lower layer stacked body T1, the middle layer stacked body T2, and the upper layer stacked body T3.

The plurality of bit lines BL1 are separated from each other in the direction X, and each bit line BL1 extends in the direction Y.

An upper end of a later-described semiconductor layer 20 (see FIG. 3) of the columnar body portion CL1 is connected to the bit line BL1 via the via contact VY1. The plurality of columnar body portions CL1 selected one by one from the respective block BLK separated in the direction Y by the slit ST is connected to one common bit line BL1.

In addition, an insulating layer is formed in the slit ST, and an insulating layer is formed on the stacked body 100. However, for convenience of explanation, these insulating layers are omitted in FIG. 1.

### [Configuration of Memory Cell]

A configuration of a memory cell according to the present embodiment will be described with reference to FIG. 3. FIG. 3 is a cross-sectional view showing a configuration of a memory cell according to the present embodiment. FIG. 3 is an enlarged cross-sectional view of the columnar body portion CL1 in FIG. 2.

As shown in FIG. 3, the columnar body portion CL1 is a structure having a memory layer 30, the semiconductor layer 20, and an insulating core layer 50. The semiconductor layer 20 extends contiguously within the stacked body 100 in the stacking direction (direction Z). For example, the material of the semiconductor layer 20 includes amorphous or polycrystalline silicon. The core layer 50 is arranged inside the cylindrical semiconductor layer 20. For example, the material of the core layer 50 includes silicon oxide. The memory layer 30 is arranged between the word line WL1 and the semiconductor layer 20. The memory layer 30 surrounds the semiconductor layer 20 from the outer periphery of the semiconductor layer 20.

The memory layer 30 includes a tunnel insulating layer 31, a charge storage layer 32, and a block insulating layer 33 (where the tunnel insulating layer 31, the charge storage layer 32, and the block insulating layer 33 are referred to as the memory layer 30 when they are not distinguished from each other). The block insulating layer 33, the charge storage layer 32, and the tunnel insulating layer 31 extend contiguously in the stacking direction of the stacked body 100 together with the semiconductor layer 20. The block insulating layer 33, the charge storage layer 32, and the tunnel insulating layer 31 are arranged from the word line WL1 side between the word line WL1 and the semiconductor layer 20. The tunnel insulating layer 31 is in contact with the semiconductor layer 20. The block insulating layer 33 is in contact with the word line WL1. The charge storage layer 32 is arranged between the block insulating layer 33 and the tunnel insulating layer 31.

The semiconductor layer 20, the memory layer 30, and the word line WL1 constitute a memory cell MC. In FIG. 3, one memory cell MC is schematically represented by a broken line. The memory cell MC has a vertical transistor structure in which the word line WL1 surrounds the periphery of the semiconductor layer 20 via the memory layer 30.

In the vertical transistor-structured memory cell MC, the semiconductor layer 20 functions as a channel and the word line WL1 functions as a control gate of the memory cell. The charge storage layer 32 functions as a data layer for storing charges injected from the semiconductor layer 20.

As described above, the plurality of memory cells MC is arranged in the stacking direction of the plurality of word lines WL1, and the plurality of word lines WL1 is connected to the plurality of memory cells MC, respectively. The word line WL1 near the block insulating layer 33 functions as the control gate. Writing to or erasing from the memory cell MC can be controlled by controlling the voltage to the word line WL1 connected to the memory cell MC.

The memory device of the present embodiment is a non-volatile semiconductor device capable of electrically freely writing or erasing data to or from the memory cell MC and holding the content even when the power is turned off.

For example, the memory cell MC is a charge-trap type memory cell. The charge storage layer 32 has a large number of trap sites that trap charges in the insulating layer. For example, the material of the charge storage layer 32 includes silicon nitride.

The tunnel insulating layer 31 serves as a potential barrier when a charge is injected from the semiconductor layer 20 into the charge storage layer 32 or when the charge accumulated in the charge storage layer 32 diffuses toward the semiconductor layer 20. For example, the material of the tunnel insulating layer 31 includes silicon oxide.

The block insulating layer 33 prevents the charges accumulated in the charge storage layer 32 from diffusing into the word line WL1. For example, the material of the block insulating layer 33 includes silicon oxide.

As shown in FIG. 2, a source-side select transistor STS is arranged in a lower layer of the stacked body 100. A drain-side select transistor STD is arranged in an upper layer of the stacked body 100. For example, the word line WL1 in the lowest layer functions as the control gate of the source-side select transistor STS. For example, the word line WL1 in the highest layer functions as the control gate of the drain-side select transistor STD. The plurality of memory cells MC is arranged between the source-side select transistor STS and the drain-side select transistor STD.

The plurality of memory cells MC is arranged between the drain-side select transistor STD and the source-side select transistor STS. The plurality of memory cells MC, the drain-side select transistor STD, and the source-side select transistor STS are connected in series through the semiconductor layer 20, and constitute one memory string. For example, the memory string is arranged in a staggered manner in a plane direction parallel to the X-Y plane, and the plurality of memory cells MC is three-dimensionally arranged in the direction X, the direction Y, and the direction Z.

### [Configuration of Connecting Region]

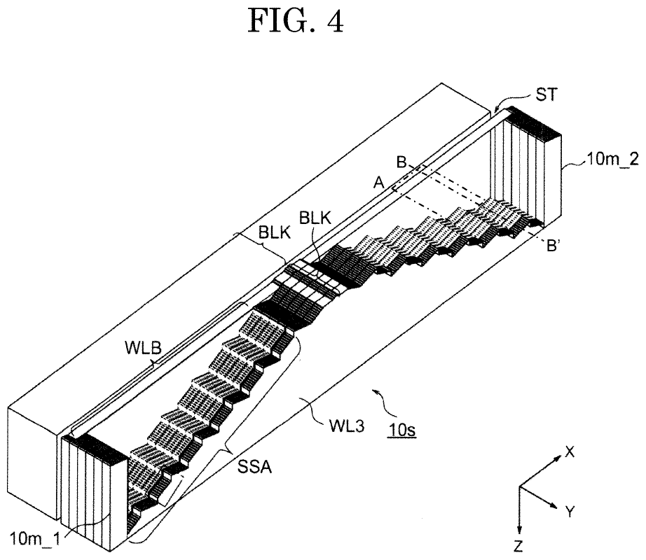

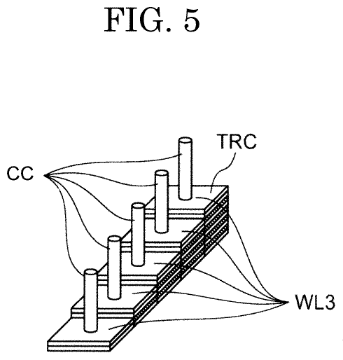

A configuration of the connecting region according to the present embodiment will be described with reference to FIG. 4 and FIG. 5. FIG. 4 is a perspective view schematically showing the connecting region 10s of a certain block BLK. FIG. 5 is an enlarged perspective view schematically showing the connecting region 10s of a certain block BLK. In addition, FIG. 4 and FIG. 5 show the memory chip C1 upside down with respect to FIG. 1. As shown in FIG. 4, a stairs region SSA of the connecting region 10s is an opening region in which the word lines WL3 are formed in a step shape. As shown in FIG. 5, a terrace region TRC for connecting the plurality of contact plugs CC to each of the plurality of word lines WL3 is arranged in the stairs region SSA. In the terrace region, the plurality of word lines WL3 is exposed from the word line WL3 of the upper stage (the CMOS chip C2 side), respectively. In addition, in the stairs region SSA, a holding member HR is formed, and an insulating body 43 is formed on (opening region) the stairs region SSA. However, for convenience of explanation, these are omitted in FIG. 4.

The bridge member WLB is composed of part of the plurality of word lines WL3, extends in the direction X (the extending direction of the slit ST), and electrically connects between the word line WL1 of the memory cell array 10m_1 and the word line WL2 of the memory cell array 10m_2 for each word line layer WL. Therefore, in the word line layer WL having the bridge member WLB, the word lines WL1 to WL3 are electrically connected with the opening region therebetween.

In the connecting region 10s, the bridge member WLB is arranged adjacent to the stairs region SSA in the direction Y (substantially perpendicular to the extending direction (direction X) of the slit ST), and is formed in a stepped shape having a steeper inclination in the direction Y as compared with the stairs region SSA, but is not formed in a stepped shape in the direction X.

### [Configuration of Bridge Member]

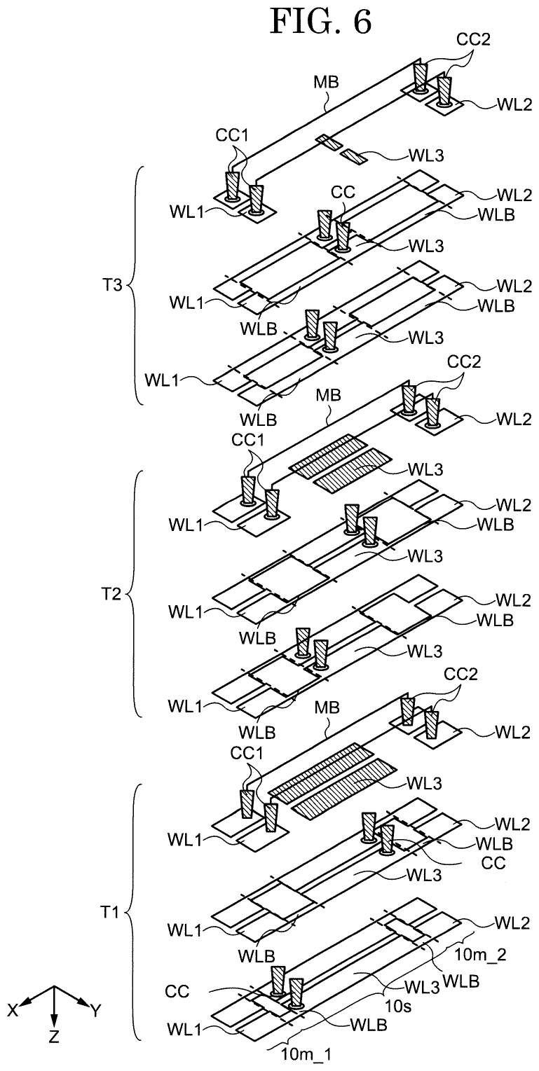

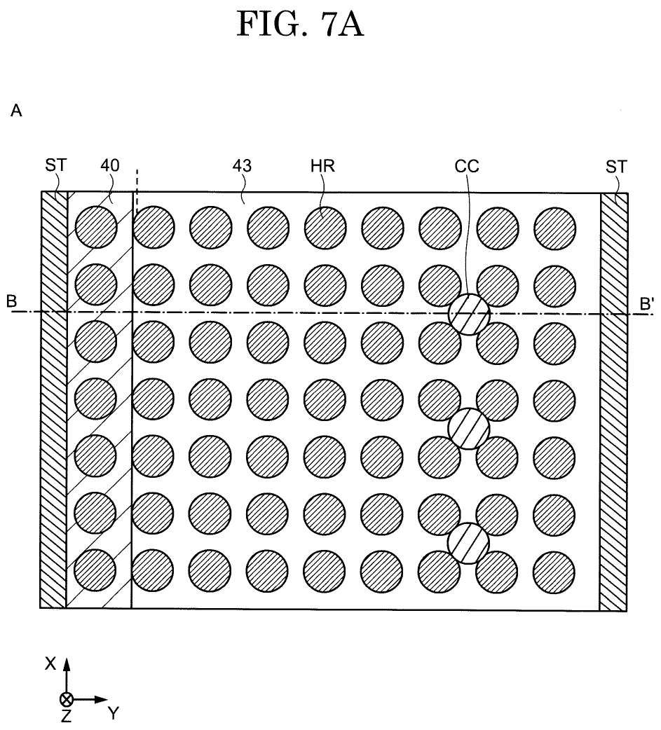

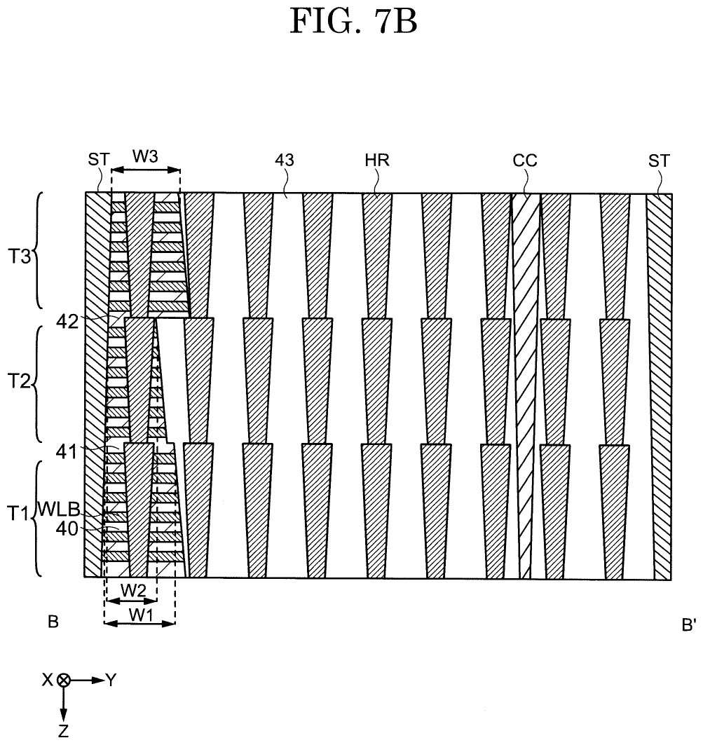

A configuration of the bridge member according to the present embodiment will be described with reference to FIG. 6, 7A, and FIG. 7B. FIG. 6 is a perspective view showing an exemplary configuration of the word lines WL1 to WL3. FIG. 7A is an enlarged top view showing part of the connecting region (region A in FIG. 4). FIG. 7B is an enlarged cross-sectional view showing part of the connecting region (B-B′ cross-section). In FIG. 6, for convenience, three word line layers are shown for each of the lower layer stacked body T1, the middle layer stacked body T2, and the upper layer stacked body T3, but the number of word lines may be four or more layers. Furthermore, in the present embodiment, a stacked group is divided into three, but may be two or less, or may be four or more. As shown in FIG. 7A and FIG. 7B, the holding member HR that penetrates the stacked body 100 and the insulating body 43 that fills the upper layer of the stairs region SSA are arranged in the stairs region SSA.

The bridge member WLB is arranged between the slit ST and the stairs region SSA. Furthermore, as shown in FIG. 7A, a width of the slit ST in the direction Y (substantially perpendicular to the extending direction (direction X) of the slit ST) is tapered so as to become narrower toward the substrate side of the stacking direction (direction Z) in the stacked body 100.

In the word line layer of the lower layer stacked body T1 relatively spaced from the CMOS chip C2, a distance between the word line WL3 and the word lines WL1 and WL2 is relatively narrow, and a length of the bridge member WLB in the direction X (the connecting direction between the word line WL3 and the word lines WL1 and WL2) is short. On the other hand, in the word line layer of the upper layer stacked body T3 relatively close to the CMOS chip C2, a distance between the word line WL3 and the word lines WL1 and WL2 is relatively wide, and the length of the bridge member WLB in the direction X is long. In the present embodiment, the word line layer of the lower layer stacked body T1 farther from the switch SW or the like of the CMOS chip C2, has a shorter length of the bridge member WLB in the direction X. The word line layer of the upper layer stacked body T3 closer to the switch SW or the like of the CMOS chip C2, has a longer length of the bridge member WLB in the direction X. That is, the length of the bridge member WLB in the direction X is longer in the middle layer stacked body T2 than in the lower layer stacked body T1, and longer in the upper layer stacked body T3 than in the middle layer stacked body T2.

A width of the bridge member WLB in the direction Y (the direction perpendicular to the connecting direction between the word line WL3 and the word lines WL1 and WL2) according to the present embodiment is different between the middle layer stacked body T2 and the upper layer stacked body T3. A width W3 of the bridge member WLB in the highest layer of the upper layer stacked body T3 in the direction Y is wider than a width W2 of the bridge member WLB in the highest layer of the middle layer stacked body T2 in the direction Y. The width of the bridge member WLB in the highest layer of the middle layer stacked body T2 in the direction Y may be in the range of 40% or more and 80% or less with respect to the width of 100% of the bridge member WLB in the highest layer of the upper layer stacked body T3 in the direction Y. In this case, the bridge member WLB in the highest layer indicates the bridge member WLB in the word line layer WL in the highest layer among the word line layer WL including the bridge member WLB (not subjected to the metal bridge MB) in each of the middle layer stacked body T2 and the upper layer stacked body T3.

Since the width W3 of the bridge member WLB in the upper layer stacked body T3 in the direction Y is wider than the width W2 of the bridge member WLB in the middle layer stacked body T2 in the direction Y, it is possible to suppress the increase in the resistance of the bridge member WLB of the upper layer stacked body T3 due to the fact that the length in the direction X of the bridge member WLB of the upper layer stacked body T3 is longer than the length in the direction X of the middle layer stacked body T2. Suppressing the increase in the resistance of the bridge member WLB makes it possible to improve the read and program operating speed of the semiconductor memory device 1. Since the width W2 of the bridge member WLB of the middle layer stacked body T2 in the direction Y is narrower than the width W3 of the bridge member WLB of the upper layer stacked body T3 in the direction Y, a space on the stairs region SSA can be secured, and the embeddability of the insulating body 43 can be improved. By improving the embeddability of the insulating body 43, it is possible to suppress the occurrence of a crack in the heat treatment step or the like, and it is possible to improve the reliability and the manufacturing yield of the semiconductor memory device 1.

The width of the bridge member WLB in the direction Y (the direction perpendicular to the connecting direction between the word line WL3 and the word lines WL1 and WL2) according to the present embodiment is different between the middle layer stacked body T2 and the lower layer stacked body T1. The width W2 of the bridge member WLB in the highest layer of the middle layer stacked body T2 in the direction Y is narrower than a width W1 of the bridge member WLB in the highest layer of the lower layer stacked body T1 in the direction Y. The width of the bridge member WLB in the highest layer of the middle layer stacked body T2 in the direction Y may be in the range of 40% or more and 80% or less with respect to the width of 100% of the bridge member WLB in the highest layer of the lower layer stacked body T1 in the direction Y. In this case, the bridge member WLB in the highest layer indicates the bridge member WLB of the word line layer WL in the highest layer among the word line layer WL including the bridge member WLB (not subjected to the metal bridge MB) in each of the lower layer stacked body T1 and the middle layer stacked body T2.

Since the width W1 of the bridge member WLB of the lower layer stacked body T1 in the direction Y is wider than the width W2 of the bridge member WLB of the middle layer stacked body T2 in the direction Y, the resistance of the bridge member WLB of the lower layer stacked body T1 can be suppressed. By suppressing the resistance of the bridge member WLB, it is possible to further improve the read and program operating speed of the semiconductor memory device 1. Since the width W2 of the bridge member WLB of the middle layer stacked body T2 in the direction Y is narrower than the width W1 of the bridge member WLB of the lower layer stacked body T1 in the direction Y, it is possible to secure a space on the stairs region SSA and improve the embeddability of the insulating body 43. By improving the embeddability of the insulating body 43, it is possible to suppress the occurrence of a crack in the heat treatment step or the like, and it is possible to improve the reliability and the manufacturing yield of the semiconductor memory device 1.

The width of the bridge member WLB in the direction Y (the direction perpendicular to the connecting direction between the word line WL3 and the word lines WL1 and WL2) according to the present embodiment may be different between the upper layer stacked body T3 and the lower layer stacked body T1. The width W3 of the bridge member WLB in the highest layer of the upper layer stacked body T3 in the direction Y may be wider than the width W1 of the bridge member WLB in the highest layer of the lower layer stacked body T1 in the direction Y. The width in the direction Y of the bridge member WLB in the highest layer of the lower layer stacked body T1 may be in a range of 50% or more and less than 100% with respect to the width 100% in the direction Y of the bridge member WLB in the highest layer of the lower layer stacked body T3. In this case, the bridge member WLB in the highest layer indicates the bridge member WLB of the word line layer WL in the highest layer among the word line layer WL including the bridge member WLB (not subjected to the metal bridge MB) in each of the lower layer stacked body T1 and the upper layer stacked body T3.

Since the width W3 of the bridge member WLB of the upper layer stacked body T3 in the direction Y is wider than the width W1 of the bridge member WLB of the lower layer stacked body T1 in the direction Y, the increase in the resistance of the bridge member WLB of the upper layer stacked body T3 due to the fact that the length in the direction X of the bridge member WLB of the upper layer stacked body T3 is longer than the length in the direction X of the bridge member WLB of the lower layer stacked body T1 can be suppressed. By suppressing the increase in the resistance of the bridge member WLB, it is possible to improve the read and programming operating speed of the semiconductor memory device 1. Since the width W1 of the bridge member WLB of the lower layer stacked body T1 in the direction Y is narrower than the width W3 of the bridge member WLB of the upper layer stacked body T3 in the direction Y, a space on the stairs region SSA can be secured, and the embeddability of the insulating body 43 can be improved. By improving the embeddability of the insulating body 43, it is possible to suppress the occurrence of a crack in the heat treatment step or the like, and it is possible to improve the reliability and the manufacturing yield of the semiconductor memory device 1.

In addition, in each of the lower layer stacked body T1, the middle layer stacked body T2, and the upper layer stacked body T3, the width of the bridge member WLB in the direction Y becomes wider in the lower layer farther from the COMS chip C2 and becomes narrower toward the CMOS chip C2. The bridge member WLB is eliminated in the word line layer in the highest layer of each of the lower layer stacked body T1, the middle layer stacked body T2, and the upper layer stacked body T3. This is because an etching process and a slimming process of a photoresist are repeatedly performed when the word line WL3 is processed into a stepped shape. In the lower layer stacked body T1, the middle layer stacked body T2, and the upper layer stacked body T3, the width of the bridge member WLB becomes narrower from the lower layer to the upper layer, and there is no bridge member WLB in the highest layer. In addition, the photoresist is reapplied to each of the lower layer stacked body T1, the middle layer stacked body T2, and the upper layer stacked body T3, and the word line WL3 is processed for each of the lower layer stacked body T1, the middle layer stacked body T2, and the upper layer stacked body T3. Therefore, the bridge member WLB in the highest layer of each of the lower layer stacked body T1, the middle layer stacked body T2, and the upper layer stacked body T3 is removed. In the word line in the highest layer, the word line WL3 is electrically floating. In addition, the word lines WL1 and WL2 in the highest layer are not connected by the bridge member WLB but are electrically connected via the metal bridge MB.

In the present embodiment, in the word line of the highest layer of each of the lower layer stacked body T1, the middle layer stacked body T2, and the upper layer stacked body T3, the metal bridge MB electrically connects the word line WL1 and the word line WL2 instead of the bridge member WLB. However, in a plurality of word line layers from the highest layer of the lower layer stacked body T1, the middle layer stacked body T2, and the upper layer stacked body T3, the metal bridge MB may electrically connect the word line WL1 and the word line WL2 instead of the bridge member WLB.

What is claimed is:

1. A semiconductor memory device comprising:
a bit line;
a first stacked body arranged above the bit line, the first stacked body including a plurality of first insulating layers and a plurality of first conductive layers alternately stacked one by one in a first direction, the first stacked body including a first stairs region and a first bridge region;
the first stairs region in which the ends of the plurality of first conductive layers are stepped in a second direction intersecting the first direction in a center of the second direction; and
the first bridge region arranged adjacent to the first stairs region in a third direction intersecting the first and second directions, and the first bridge region electrically connects memory cell regions on both sides of the first stairs region in the second direction for each of the plurality of first conductive layers, and
a second stacked body arranged above the first stacked body, the second stacked body including a plurality of second insulating layers and a plurality of second conductive layers alternately stacked one by one in the first direction, the second stacked body including a second stairs region and a second bridge region;
the second stairs region in which the ends of the plurality of second conductive layers are stepped in the second direction in the center of the second direction; and
the second bridge region arranged adjacent to the second stairs region in the third direction, and the second bridge region electrically connects memory cell regions on both sides of the second stairs region in the second direction for each of the plurality of second conductive layers,
wherein a width of a lowest layer of the plurality of first conductive layers of the first bridge region in the third direction is larger than a width of a lowest layer of the plurality of second conductive layers of the second bridge region in the third direction.

2. The semiconductor memory device according to claim 1, wherein;
the width of the lowest layer of the plurality of second conductive layers of the second bridge region in the third direction is in the range of 40% or more and 80% or less with respect to the width of the lowest layer of the plurality of first conductive layers of the first bridge region in the third direction, which is 100%.

3. The semiconductor memory device according to claim 1, further comprising:
a third stacked body arranged above the second stacked body, the third stacked body including a plurality of third insulating layers and a plurality of third conductive layers alternately stacked one by one in the first direction, the third stacked body including a third stairs region and a third bridge region;
the third stairs region in which the ends of the plurality of third conductive layers are stepped in the second direction in the center of the second direction; and
the third bridge region arranged adjacent to the third stairs region in the third direction, and the third bridge region electrically connects memory cell regions on both sides of the third stairs region in the second direction for each of the plurality of third conductive layers,
wherein a width of a lowest layer of the plurality of third conductive layers of the third bridge region in the third direction is larger than a width of a lowest layer of the plurality of second conductive layers of the second bridge region in the third direction.

4. The semiconductor memory device according to claim 3, wherein;
the width of the lowest layer of the plurality of second conductive layers of the second bridge region in the third direction is in the range of 40% or more and 80% or less with respect to the width of the lowest layer of the plurality of third conductive layers of the third bridge region in the third direction, which is 100%.

5. The semiconductor memory device according to claim 3, wherein;
the width of a lowest layer of the plurality of first conductive layers of the first bridge region in the third direction is larger than a width of a lowest layer of the plurality of third conductive layers of the third bridge region in the third direction.

6. The semiconductor memory device according to claim 5, wherein;
the width of the lowest layer of the plurality of third conductive layers of the third bridge region in the third direction is in the range of 50% or more and less than 100% with respect to the width of the lowest layer of the plurality of first conductive layers of the first bridge region in the third direction, which is 100%.
